(19) United States
(12) Patent Application Publication
(10) Pub. No.: US 2014/0017487 A1
(43) Pub. Date: Jan. 16, 2014

(54) INSULATION FILM HAVING METAL LAYER

(71) Applicant: SAMSUNG ELECTRO-MECHANICS CO., LTD., Suwon (KR)

(72) Inventors: Hee Sun Chun, Suwon (KR); Jae Choon Cho, Suwon (KR); Choon Keun Lee, Suwon (KR)

(21) Appl. No.: 13/938,054

(22) Filed: Jul. 9, 2013

(30) Foreign Application Priority Data
Jul. 13, 2012 (KR) 10-2012-0076609

(51) Int. Cl. H05K 1/02

(52) U.S. Cl. CPC H05K 1/0298
USPC 428/336; 428/457; 428/337

(57) ABSTRACT

Disclosed herein is an insulation film having a metal layer, including: a carrier; a metal layer formed on the carrier; and an insulation layer formed on the metal layer.

### CROSS REFERENCE TO RELATED APPLICATION

This application claims the benefit of Korean Patent Application No. 10-2012-0076609, filed on Jul. 13, 2012, entitled “Insulation film Having Metal Layer”, which is hereby incorporated by reference in its entirety into this application.

### BACKGROUND OF THE INVENTION

1. Technical Field

The present invention relates to an insulation film having a metal layer.

2. Description of the Related Art

A printed circuit board has recently used a build-up insulation film in order to implement and develop thinness, high integration, and a micro-circuit for coping with high specification.

In this case, the used build-up insulation film has developed for the purpose of having low thermal expansion rate in order to minimize defect according to the thermal expansion rate at the time of forming a micro circuit pattern.

In order to manufacture the insulating film having the above-mentioned low thermal expansion rate, content of an inorganic filler mixed in an insulating material needs to be increased. However, in the case in which the content of the inorganic filler in the insulation film is increased, adhesion between the insulation film and a plating layer formed on the insulation film may be reduced.

Meanwhile, the insulation film according to the prior art has been disclosed in Japanese Patent Laid-Open Publication No. 2003-283113.

### SUMMARY OF THE INVENTION

The present invention has been made in effort to provide an insulation film having a metal layer capable of increasing adhesion between a plating layer and an insulation layer.

The present invention has been made in effort to provide an insulation film having a metal layer capable of decreasing a waste of a subsidiary material.

The present invention has been made in effort to provide an insulation film having a metal layer capable of improve process efficiency of manufacturing a substrate.

According to a preferred embodiment of the present invention, there is provided an insulation film having a metal layer, including: a carrier; a metal layer formed on the carrier; and an insulation layer formed on the metal layer.

The carrier may be made of copper (Cu).

The carrier may have a thickness of 18 μm to 35 μm.

The metal layer may be made of copper (Cu).

The metal layer may have a thickness of 100 nm to 3000 nm.

The insulation layer may have a thickness of 10 μm to 40 μm.

The insulation layer may be made of a resin insulation material having an inorganic filler included therein.

According to another preferred embodiment of the present invention, there is provided an insulation film having a metal layer, including: an insulation layer; and a metal layer formed on the insulation layer.

The insulation layer may have a thickness of 10 μm to 40 μm.

The insulation layer may be made of a resin insulation material having an inorganic filler included therein.

The metal layer may be made of copper (Cu).

The metal layer may have a thickness of 100 nm to 3000 nm.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a cross-sectional view showing a structure of an insulation film having a metal layer according to a preferred embodiment of the present invention;

FIG. 2 is a cross-sectional view showing a structure of an insulation film having a metal layer according to another preferred embodiment of the present invention; and

FIG. 3 is a cross-sectional view showing a process separating a carrier and an insulation film at the time of manufacturing the insulation film having the metal layer shown in FIG. 2.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

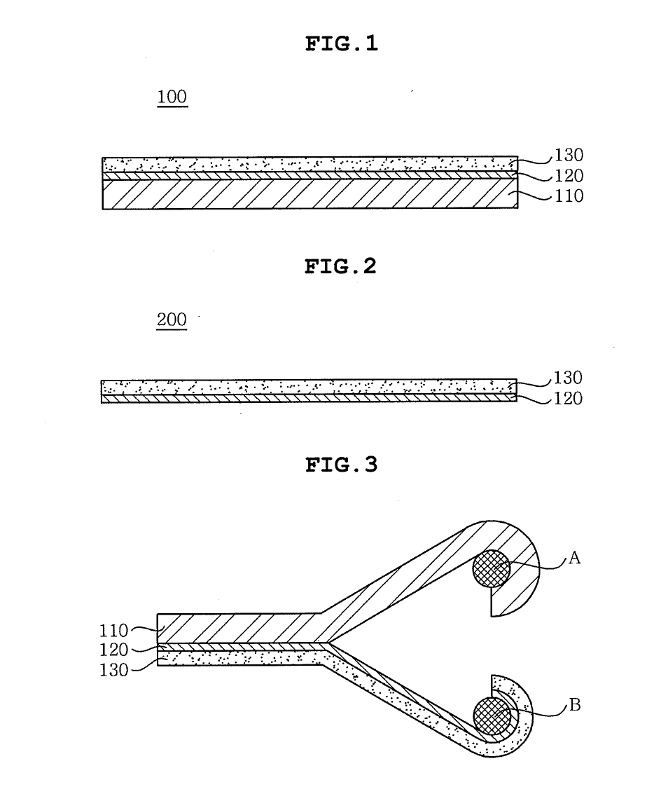

FIG. 1 is a cross-sectional view showing a structure of an insulation film having a metal layer according to a preferred embodiment of the present invention, FIG. 2 is a cross-sectional view showing a structure of an insulation film having a metal layer according to another preferred embodiment of the present invention, and FIG. 3 is a cross-sectional view showing a process separating a carrier and an insulation film at the time of manufacturing the insulation film having the metal layer shown in FIG. 2.

Referring to FIG. 1, an insulation film 100 having a metal layer according to a preferred embodiment of the present invention may include a carrier 110, a metal layer 120, and an insulation layer 130. According to the preferred embodiment of the present invention, the carrier 110 may be made of a metal, but is not particularly limited thereto.

Here, an example of the above-mentioned metal may include copper (Cu), but is not particularly limited thereto and it is also possible to use aluminum (Al), or the like.

Since the carrier 110 according to the preferred embodiment of the present invention serves as a support, it is preferable that a thickness thereof is not formed to be excessively small in order to improve handling property. The thickness of the carrier 110 according to the preferred embodiment of the present invention may be in a range of 18 μm to 35 μm, but is not particularly limited thereto.

The metal layer 120 according to the preferred embodiment of the present invention may be made of copper (Cu), but is not particularly limited thereto. The metal layer 120 may also be made of gold (Au), silver (Ag), aluminum (Al), cobalt (Co), chromium (Cr), nickel (Ni), titanium (Ti), tungsten (W), zinc (Zn) iron (Fe), tin (Sn), or an alloy thereof.

The thickness of the metal layer 120 according to the preferred embodiment of the present invention may be in a range of 100 nm to 3000 nm, but is not particularly limited thereof.

In the case in which the thickness of the metal layer is excessively small, a crack may be generated at the metal layer after manufacturing the insulation film 100 and the metal layer may also be easily removed by a desmear process of the substrate manufacturing process.

Meanwhile, in the case in which the thickness of the metal layer 120 is excessively large, a long time is required to form the metal layer 120, such that process time and process cost may be increased.

The formation of the metal layer 120 on the carrier 110 according to the preferred embodiment of the present invention may be performed by a plating process, but is not particularly limited thereto. The metal layer 120 may also be formed by compressing a metal foil having a foil form on the carrier 110 and formed by depositing by a sputtering process. In addition, all of the technologies of forming the metal layer known in the art in addition to this may be applied.

As the insulation layer 130 according to the preferred embodiment of the present invention, a resin insulation material may be used. In this case, the resin insulation material may contain an inorganic filler, and the inorganic filler may be silica, or the like, but is not particularly limited thereto.

As the resin insulation material, a thermo-setting resin such as an epoxy resin, a thermo-plastic resin such as polyimide, a resin having a reinforcement material such as a glass fiber impregnated therein, for example, a prepreg may be used. In addition, a thermo-setting resin, a photo-setting resin, and/or the like, may be used, but the resin insulation material is not particularly limited thereto.

The thickness of the metal layer 130 according to the preferred embodiment of the present invention may be in a range of 10 μm to 40 μm, but is not particularly limited thereof.

In the case in which the thickness of the insulation layer is out of the above-mentioned range, a problem of interlayer insulation reliability may be generated.

The formation of the insulation layer 130 on the metal layer 120 according to the preferred embodiment of the present invention may be performed by applying a liquid phase insulation material on the metal layer 120 and then drying the applied insulation material, but is not particularly limited thereto. In addition, the insulation layer 130 may also be formed by compressing an insulation material having a film form on the metal layer 120.

In addition, the insulation film 100 having the metal layer according to the preferred embodiment of the present invention may further include a cover film (not shown) formed on the insulation layer 130.

The cover film (not shown) is formed to serve to protect the insulation layer 130 from the outside.

As such, according to the preferred embodiment of the present invention, a release interface is provided between the carrier 110 and the metal layer 120 by using a metal foil made of copper (cu) as the carrier 110 and forming the metal layer 120 on the carrier 110, such that the carrier 110 and the metal layer 120 may be easily separated, thereby making it possible to reuse the carrier 110. Therefore, a subsidiary material and cost may be decreased.

In addition, the insulation layer 130 having the inorganic filler contained therein and the metal layer 120 are integrally formed, such that adhesion between a plating layer formed on the metal layer 120 and the insulation layer at the time of manufacturing the substrate later may be improved.

In addition, according to another preferred embodiment of the present invention, an insulation film 200 having the metal layer as shown in FIG. 2 is provided.

Referring to FIG. 2, the insulation film 200 having the metal layer according to another preferred embodiment of the present invention may include the insulation layer 130 and the metal layer 120 formed on the insulation layer 130.

The above-mentioned structure may be obtained by removing the carrier 110 from the insulation film 100 having the metal layer shown in FIG. 1.

That is, the insulation film 200 having the metal layer according to another preferred embodiment of the present invention may obtained by forming the metal layer 120 on the carrier 110 and forming the insulation layer 130 on the metal layer 120 as described above, and then separating the carrier 110 and the metal layer 120.

In this case, the separation of the carrier 110 and the metal layer 120 may be performed by winding the carrier 110 and the metal layer 120/the insulation layer 130 around each of rollers A and B as shown in FIG. 3, but is not particularly limited thereto.

As such, since there is no need for a process of removing the carrier 110 of the substrate manufacturing process to be performed later by manufacturing the insulation film 200 having the metal layer with the carrier 110 removed, as the number of processes is deceased, the processing time is shortened. As a result, improvement of process efficiency may be additionally obtained.

The present invention uses a metal as a carrier and forms a metal layer on the carrier through a plating process to thereby provide a release interface between the carrier and the metal layer, such that the carrier and the metal layer is easily separated and the carrier may be reused, thereby making it possible to decrease the waste of the subsidiary material.

In addition, the present invention manufactures a complete product in which the carrier is removed, such that a carrier removing process of the substrate manufacturing processes is removed, thereby making it possible to increase process efficiency.

In addition, the present invention may improve the adhesion between the plating layer and the insulation layer by forming the plating layer on the metal layer at the time of manufacturing the substrate, using the insulation film having the metal layer.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. An insulation film having a metal layer, comprising:
a carrier;
a metal layer formed on the carrier; and
an insulation layer formed on the metal layer.

2. The insulating film as set forth in claim 1, wherein the carrier is made of copper (Cu).

3. The insulating film as set forth in claim 1, wherein the carrier has a thickness of 18 μm to 35 μm.

4. The insulating film as set forth in claim 1, wherein the metal layer is made of copper (Cu).

5. The insulating film as set forth in claim 1, wherein the metal layer has a thickness of 100 nm to 3000 nm.

6. The insulating film as set forth in claim 1, wherein the insulation layer has a thickness of 10 μm to 40 μm.

7. The insulating film as set forth in claim 1, wherein the insulation layer is made of a resin insulation material having an inorganic filler included therein.

8. An insulation film having a metal layer, comprising:
an insulation layer; and
a metal layer formed on the insulation layer.

9. The insulating film as set forth in claim 8, wherein the insulation layer has a thickness of 10 μm to 40 μm.

10. The insulating film as set forth in claim 8, wherein the insulation layer is made of a resin insulation material having an inorganic filler included therein.

11. The insulating film as set forth in claim 8, wherein the metal layer is made of copper (Cu).

12. The insulating film as set forth in claim 8, wherein the metal layer has a thickness of 100 nm to 3000 nm.
